(19) United States
(12) Patent Application Publication
(10) Pub. No.: US 2026/0268746 A1
(43) Pub. Date: Sep. 10, 2026

(54) INTEGRATED TACTILE SENSING DEVICE FOR COMPUTING SYSTEMS

(71) Applicant: QUANTA COMPUTER INC., Taoyuan City (TW)

(72) Inventors: Yaw-Tzorng TSORNG, Taoyuan City (TW); Jen-Jia LIOU, Taoyuan City (TW); Wei-Jie CHEN, Taoyuan City (TW); Yu-Tung YANG, Taoyuan City (TW)

(21) Appl. No.: 19/073,538

(22) Filed: Mar. 7, 2025

(51) Int. Cl. G08B 6/00; H05K 7/14

(52) U.S. Cl. CPC G08B 6/00; H05K 7/1495

(57) ABSTRACT

A tactile sensing device and method for a computing system include a movable component, a non-movable component, a spring, and a tactile switch. The movable component is engaged with the non-movable component in a first position and disengaged from the non-movable component in a second position. The spring is attached to the movable component and has a spring arm. The tactile switch is in contact with the non-movable component. The tactile switch has a tactile arm. In the first position, the tactile arm is in direct contact with and compressed by the spring arm. In response to movement of the movable component from the first position to the second position, the spring arm moves out of contact with the tactile arm causing the tactile switch to output an alert that the movable component is in the second position.

### FIELD OF THE INVENTION

The present invention relates generally to a computing system, and more specifically, to an integrated tactile sensing device and method for monitoring movements of a movable component of a computing system.

### BACKGROUND OF THE INVENTION

Modern computing systems, such as servers, generally require high level of cybersecurity to provide secure and reliable computing operations. To achieve optimal server cybersecurity, various technologies, tools, and practices have been developed to safeguard servers from unauthorized access, data breaches, and other security threats. The implementation of many critical measures not only ensures server cybersecurity, but also minimizes or eliminates any downtime caused by cybersecurity issues. Current technologies are categorized to digital cybersecurity measures and physical cybersecurity measures. On one hand, digital cybersecurity measures can be implemented to achieve a high level of cybersecurity in businesses including data centers. These measures include antivirus software and firewall. On the other hand, physical cybersecurity such as chassis intrusion detection and protection can help a computing system achieve a higher level of cybersecurity. Chassis intrusion detection is a physical safeguard measure designed to protect integrity of the computing system from tampering.

A typical chassis intrusion detection design utilizes a chassis intrusion detection device, such as a tactile switch. The purpose of the tactile switch is to detect when a movable component becomes detached. Upon detection, the tactile switch immediately sends a notification to alert monitoring personnel. For example, when a top cover of a sever is removed or opened, that movement triggers the tactile switch which alerts a system administrator. In this case, the tactile switch is misaligned or disengaged because the cover is opened or not properly seated on the chassis of the server. This prior design, however, normally cannot detect both sliding and pivoting/flipping movements of the top cover with one tactile switch. Thus, in previous designs, detection of both movements requires the installation of separate mechanisms — one for sliding contact and another for vertical pressing contact. Accordingly, there is a need to detect sliding contacts without the need to install an additional tactile switch to detect vertical contacts, ensuring that a simple design can effectively detect different triggering conditions. Further, this simple design simplifies the assembly process, reduces installation complexity, and enhances overall efficiency of the chassis intrusion detection device.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a tactile sensing device and method for a computing system include a movable component, a non-movable component, a spring, and a tactile switch. The movable component is engaged with the non-movable component in a first position and disengaged from the non-movable component in a second position. The spring is attached to the movable component and has a spring arm. The tactile switch is in contact with the non-movable component. The tactile switch has a tactile arm and an actuator. In the first position, the tactile arm is in direct contact with and compressed by the spring arm. Additionally, the actuator is in direct contact with and compressed by the tactile arm. In response to movement of the movable component from the first position to the second position, the spring arm moves into the second position and out of contact with the tactile arm. Accordingly, the tactile arm moves out of contact with the actuator and thus causing the tactile switch to output an alert that the movable component is in the second position.

According to a configuration of the above implementation, the tactile sensing device includes a switch holder that is mounted on the non-movable component.

According to another configuration of the above implementation, the switch holder is mounted on an interior surface of the non-movable component.

According to yet another configuration of the above implementation, the spring further includes a base and a support. The support couples the base and the spring arm on opposite ends of the support. The base is mounted on an interior surface of the movable component.

According to a further configuration of the above implementation, the spring arm is oriented at an angle between about 0 degrees to about 90 degrees relative to the base.

According to one aspect of the present disclosure, the tactile arm has a curved end that is configured to engage with the spring arm.

According to a configuration of the above implementation, the curved end of the tactile arm has an arc shape.

According to another configuration of the above implementation, the non-movable component is a sidewall of a chassis of the computing system.

According to yet another configuration of the above implementation, the movable component is a cover.

According to a further configuration of the above implementation, the computing system is a server.

According to another aspect of the present disclosure, the tactile switch has a longitudinal body, and the actuator is vertically positioned on the longitudinal body.

According to a configuration of the above implementation, the movable component is configured to slide, in parallel with the longitudinal body, or pivot, normally to the longitudinal body, out of engagement with the non-movable component.

According to another aspect of the present disclosure, a computing system includes a movable component and a non-movable component. The movable component is engaged with the non-movable component in a first position and disengaged from the non-movable component in a second position. The computing system further includes a tactile sensing device. The tactile sensing device is configured to detect movements of the movable component from the first position to the second position. Moreover, the tactile sensing device includes a spring, a tactile switch, and a control system. The spring is in contact with the movable component and has a spring arm. The tactile switch is in contact with the non-movable component. The tactile switch has a tactile arm and an actuator. The tactile arm is in direct contact with and compressed by the spring arm in the first position. In response to movement of the movable component from the first position to the second position, the spring arm is movable to the second position in which the spring arm is out of contact with the tactile arm. The actuator is in direct contact with and compressed by the tactile arm in the first position, and uncompressed in the second position. Further, the control system has one or more processors configured to execute machine-executable instructions to cause the computing system to monitor the tactile switch of the tactile sensing device. Upon detection of the second position, the control system outputs an alert that the movable component is in the second position.

According to a configuration of the above implementation, the tactile switch is at an ON state when the spring arm is in the first position. Additionally, the tactile switch is at an OFF state when the spring arm is in the second position.

According to another configuration of the above implementation, the control system monitors the ON state and the OFF state of the tactile switch. When the tactile switch changes from the ON state to the OFF state, the control system outputs the alert.

According to yet another aspect of the present disclosure, a method is designed to detect movements for a movable component of a computing system. The method includes mounting a tactile switch to a non-movable component of the computing system. The tactile switch has a tactile arm and an actuator. Additionally, a spring is mounted to an interior surface of the movable component. The spring has a spring arm. The method further includes engaging the movable component with the non-movable component in a first position. In the first position, the tactile arm is in direct contact with and compressed by the spring arm. Moreover, the actuator is in direct contact with and compressed by the tactile arm. Furthermore, the method includes monitoring an OFF state of the tactile switch when the movable component is disengaged from the non-movable component in a second position. In the second position, the spring arm moves out of direct contact with the tactile arm causing the actuator to disengage with the tactile arm. Upon detection of the OFF state, the method outputs an alert that the movable component is in the second position.

According to a configuration of the above implementation, the method further includes sending the alert to a personal computing device of a user, the personal computing device being communicatively coupled with the computing system.

According to another configuration of the above implementation, the tactile switch has a longitudinal body, and the actuator is vertically positioned on the longitudinal body.

According to yet another configuration of the above implementation, the movable component is configured to slide, in parallel with the longitudinal body, or pivot, normally to the longitudinal body, out of contact with the non-movable component.

According to a further configuration of the above implementation, the method includes coupling the tactile switch to a switch holder and mounting the switch holder to the non-movable component.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is an isometric perspective view showing a tactile sensing device of a computing system, according to certain aspects of the present disclosure.

FIG. 2 is an exploded sectional view of a section A indicated in FIG. 1 showing a tactile switch of the tactile sensing device attached to a non-movable component of the computing system, according to certain aspects of the present disclosure.

FIG. 3 is an exploded sectional view of a section B indicated in FIG. 1 showing a spring of the tactile sensing device attached to a movable component of the computing system, according to certain aspects of the present disclosure.

FIG. 4 is a right side view of the tactile sensing device of the computing system showing the movable component being at a first position where the spring is engaged with the tactile switch, according to certain aspects of the present disclosure.

FIG. 5 is a right side view of the tactile sensing device of the computing system showing the movable component being at a second position where the spring is disengaged with the tactile switch, according to certain aspects of the present disclosure.

FIG. 6 is a right side view of the tactile sensing device of the computing system showing the movable component being at a second position where the movable component is pivoted away from the tactile switch, according to certain aspects of the present disclosure.

FIG. 7 is a flowchart diagram of a computing system showing a control system being communicatively connected with a tactile switch and a personal computing device of a user, according to certain aspects of the present disclosure.

FIG. 8 is a flowchart diagram of a computing system showing a control system configured to monitor movements of a movable component via a tactile switch, according to certain aspects of the present disclosure.

FIG. 9 is a flowchart diagram showing a method for monitoring movements of a movable component with respect with a non-movable component of a computing system using a tactile sensing device, according to certain aspects of the present disclosure.

FIG. 10 is a flowchart diagram showing alternative methods for monitoring movements of a movable component with respect with a non-movable component of a computing system using a tactile sensing device, according to certain aspects of the present disclosure.

### DETAILED DESCRIPTION

An integrated tactile sensing device for a computing system is designed to efficiently and precisely monitor movements of a movable component, such as a cover, with respect to a non-movable component, such as a chassis sidewall. The movable component is engaged with the non-movable component in a first position, e.g., a closed position of the cover to enclose the chassis. Additionally, the movable component is disengaged with the non-movable component in a second position, e.g., an open position where the cover either slides or pivots off the chassis sidewall.

The tactile sensing device includes a spring and a tactile switch. The spring is attached to and in contact with the movable component. The spring has a spring arm. The tactile switch is in contact with the non-movable component. The tactile switch has a tactile arm and an actuator. With the movable component at the first position, the tactile arm is in direct contact with the spring. Additionally, the tactile arm is compressed on the actuator by the spring arm. In response to movement of the movable component from the first position to the second position, the spring arm is movable to the second position. This movement results in the spring arm moving out of contact with the tactile arm. Moreover, in the second position, the actuator is uncompressed by the tactile arm. Furthermore, in response to the spring arm being in the second position, the tactile switch outputs an alert that the movable component is in the second position. Thus, by integrating the tactile switch with the spring, the tactile sensing device monitors the movements of the movable component caused by sliding, pivoting, and/or flipping actions.

Accordingly, the tactile sensing device provides precise detections of the movable component being disengaged from the non-movable component using one tactile switch integrated with the spring. This design and structure allow the tactile switch to detect the disengagement of the movable component under two triggering conditions: (1) the horizontal contact via a sliding movement; and (2) the vertical contact via a pivoting movement. These two triggering conditions conventionally require two separate tactile switches. Thus, the tactile sensing device simplifies the assembly process, reduces installation complexity, and enhances overall efficiency comparing with prior devices.

For example, the tactile sensing device is used to detect if a top cover of a server is opened. The top cover either sides open or flips/pivots open, thus causing the disengagement from a chassis of the server. This disengagement via sliding movement triggers the sliding contact of the tactile switch while flipping/pivoting movement triggers a vertical downward contact. Both types of movement result in the spring moving out of contact with the tactile switch. Moreover, the spring is designed to be reusable. Thus, the tactile sensing device provides precise detections under both triggering conditions without two separate tactile switches. By integrating the spring with the tactile switch, the tactile sensing device prevents or eliminates false alarms and over-pressing that causes damage to the tactile switch.

A method is designed to integrate a spring with a tactile switch to accurately monitor movements of a movable component with respect to a non-movable component of a computing system, such as a server. The method includes mounting the tactile switch to the non-movable component of the computing system. The tactile switch has a tactile arm and an actuator. The method also includes mounting a spring to an interior surface of the movable component. The spring has a spring arm. Moreover, the method includes engaging the movable component with the non-movable component in a first position. At the first position, the tactile arm is in direct contact with and compressed by the spring arm. Additionally, the actuator is in direct contact with and compressed by the tactile arm in the first position. The tactile switch has an ON state and an OFF state. The ON state corresponds to when the movable component is engaged with the non-movable component in the first position. The OFF state, on the other hand, is when the movable component is disengaged from the non-movable component in the second position, and thus the spring arm moves out of direct contact with the tactile arm causing the actuator to disengage from the tactile arm. The method further includes monitoring the OFF state of the tactile switch and outputs an alert that the movable component is in the second position.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

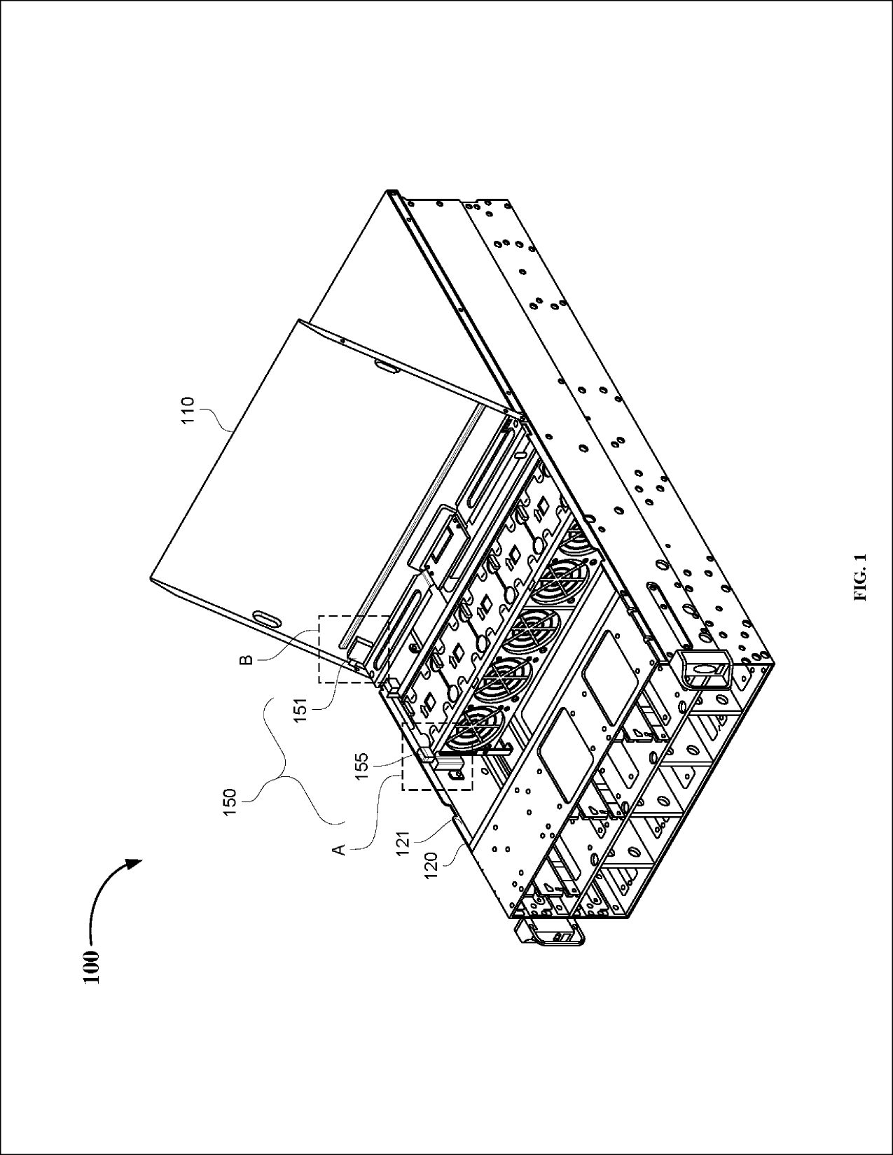

FIG. 1 illustrates a tactile sensing device 150 of a computing system 100. Specifically, the computing system 100 includes a movable component 110, such as a cover of a server, and a non-movable component 120, such as a side wall of a chassis. The movable component 110 has an interior surface 121. In some implementations, the movable component 110 slides along and/or pivots from the non-movable component 120. For example, as shown in FIG. 1, the movable component 110 pivots with respect to the non-movable component 120 to open or close the computing system 100. Moreover, the tactile sensing device 150 has a spring 151 and a tactile switch 155. The spring 151 is attached to and in contact with the movable component 110. Further, the tactile switch 155 is attached to and in contact with the interior surface 121 of the non-movable component 120.

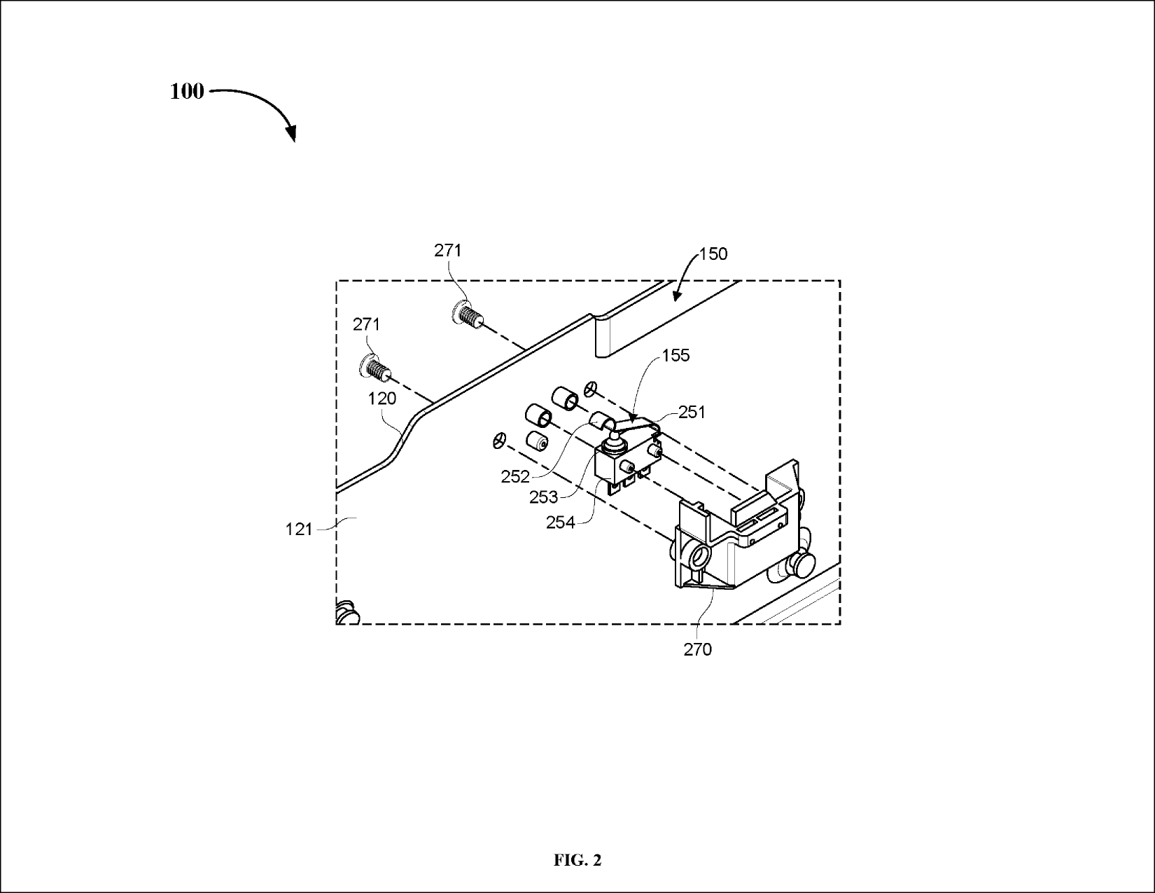

FIG. 2 illustrates the tactile switch 155 of the tactile sensing device 150 of the computing system 100 by an exploded sectional view of a section A indicated in FIG. 1. The tactile switch 155 is attached to and in contact with the interior surface 121 of the non-movable component 120. Additionally, the tactile switch 155 includes a longitudinal body 254, a tactile arm 251, and an actuator 253. The actuator 253 is vertically positioned on the longitudinal body 254. The tactile arm 251 is attached to the longitudinal body 254. The tactile arm 251 has a curved end 252. In some implementations, the curved end 252 has an arc shape.

As shown in FIG. 2, the tactile sensing device 150 further includes a switch holder 270. The switch holder 270 is designed to secure and protect the tactile switch 155. Specifically, the tactile switch 155 is attached to the switch holder 270, which is then securely attached to the non-movable component 120. In some implementations, the switch holder 270 is mounted to the non-movable component 120 using one or more fasteners 271.

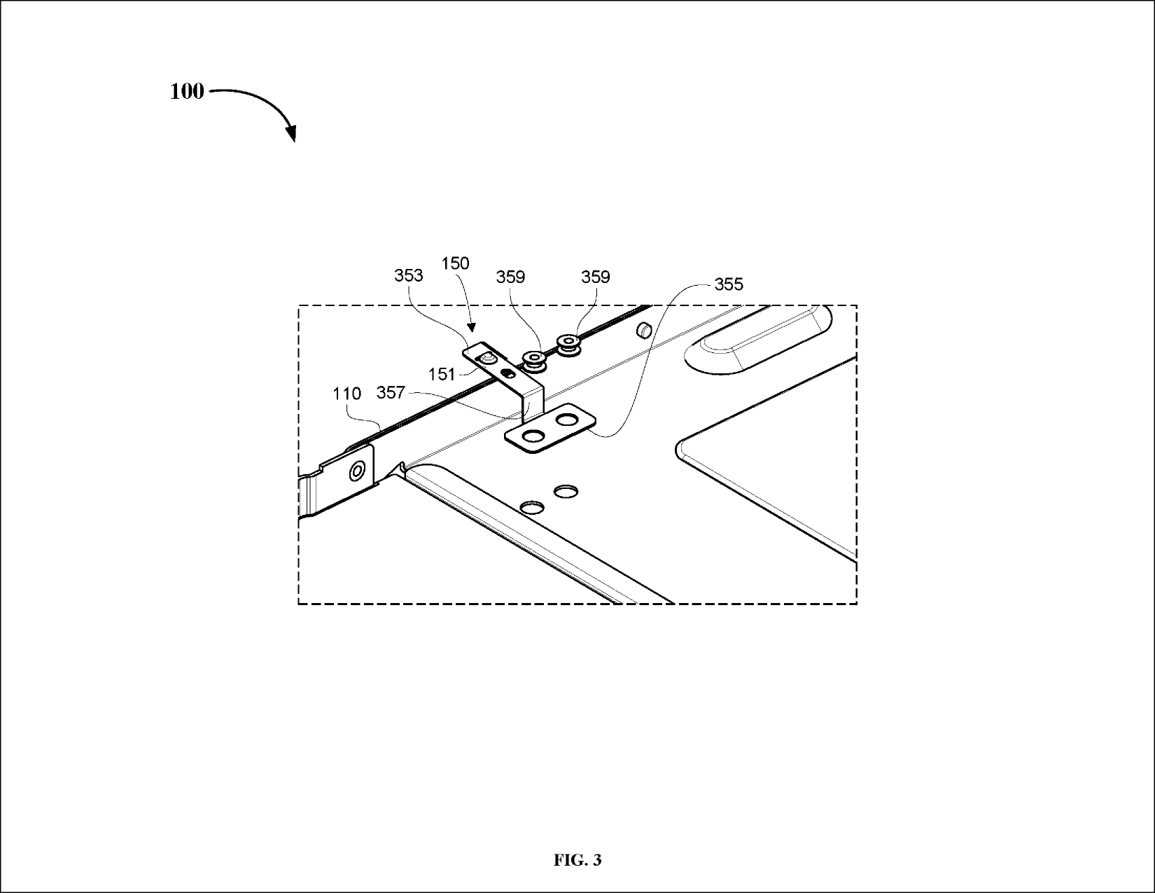

FIG. 3 illustrates the spring 151 of the tactile sensing device 150 by a sectional view of a section B indicated in FIG. 1. The spring 151 is attached to the movable component 110 of the computing system 100. The spring 151 includes a base 355, a support 357, and a spring arm 353. The support 357 is designed to couple, on opposite ends, the base 355 and the spring arm 353. Moreover, the base 355 is mounted on an interior surface of the movable component 110. For example, the base 355 is mounted on the movable component 110 using one or more spring fasteners 359. Further, the spring arm 353 is oriented at an angle between about 0 degrees to about 90 degrees relative to the base 355. This design allows the spring arm 353 to efficiently slide or pivot into engagement with the tactile switch 155. In some implementations, this angle is determined based on estimates and experiences including dimensional tolerance calculations and/or analyses. The angle of the spring arm 353 allows the spring 151 to be compressed when engaged with the tactile switch 155 and to restore when disengaged.

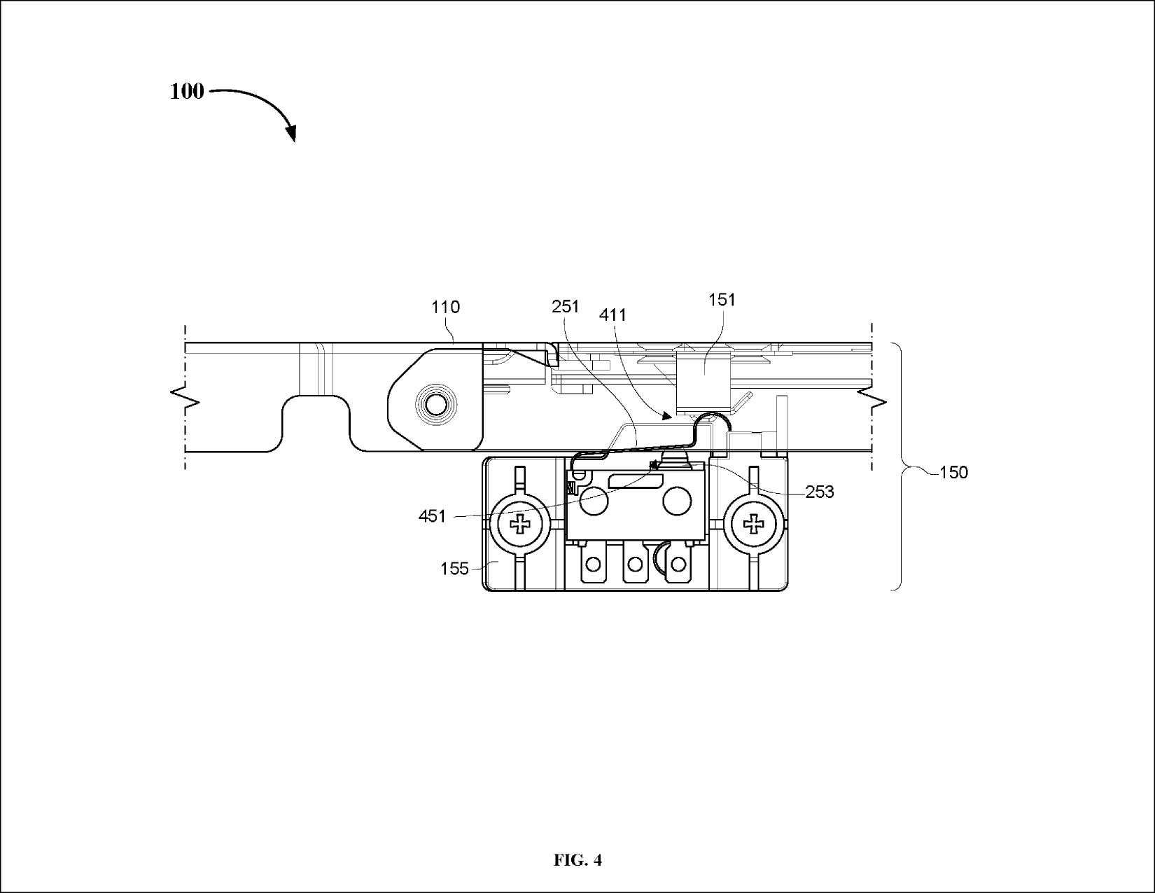

FIG. 4 illustrates the tactile sensing device 150 of the computing system 100 when the movable component 110 is in a first position 411. In the first position 411, the spring 151 is engaged with the tactile switch 155. Specifically, the tactile arm 251 of the tactile switch 155 is in direct contact with and compressed by the spring arm 353 (shown in FIG. 3). Additionally, the actuator 253 of the tactile switch 155 is in direct contact with and compressed by the tactile arm 251, thus causing the tactile switch 155 to be at an ON state 451. For example, the ON state 451 of the tactile switch 155 corresponds to a condition that the movable component 110 is in the first position 411 and engaged with the non-movable component 120 (shown in FIG. 1 and FIG. 2).

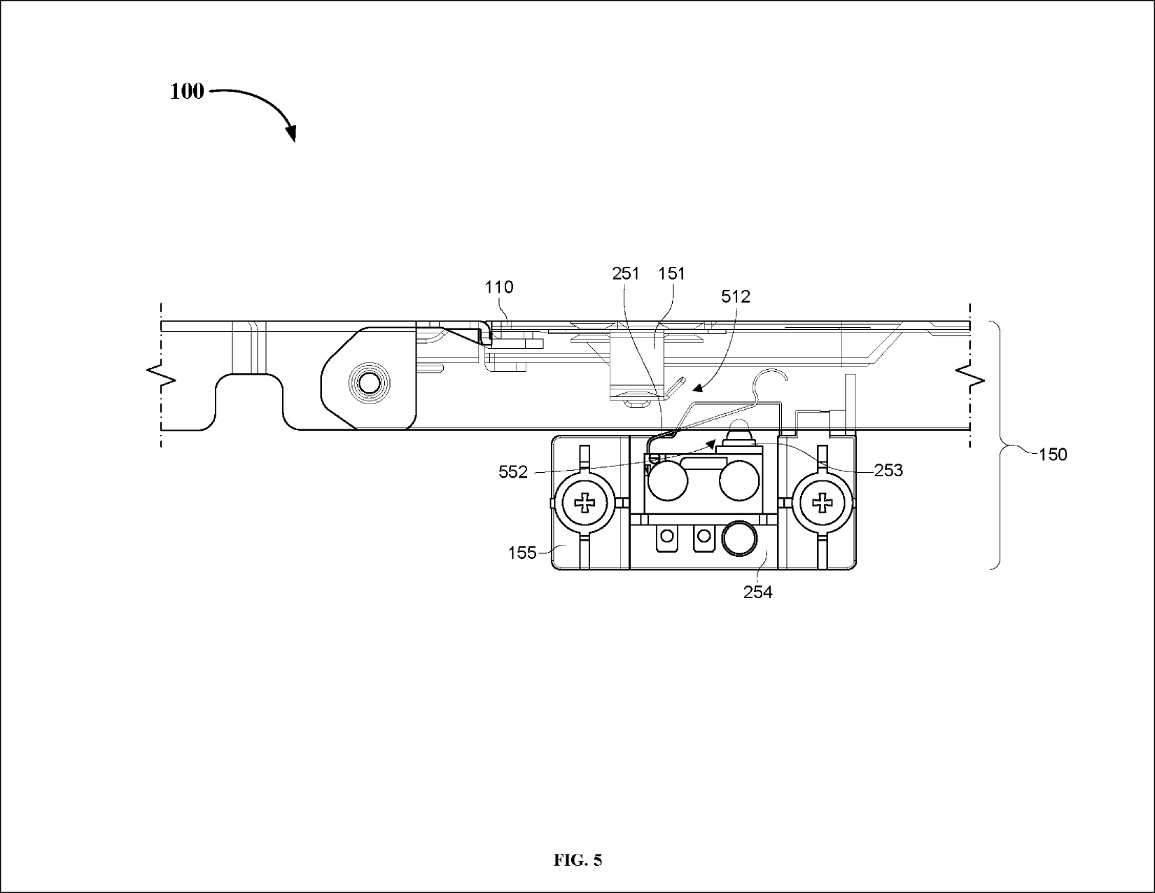

FIG. 5 illustrates the tactile sensing device 150 of the computing system 100 when the movable component 110 is in a second position 512. In the second position 512, the spring 151 is disengaged with the tactile switch 155. Specifically, the movable component 110 moves out of engagement with the non-movable component 120, as shown in FIG. 1. In some implementations, the movable component 110 slides in parallel with respect to the longitudinal body 254 of the tactile switch 155. This parallel movement causes the movable component 110 to move from the first position 411 (shown in FIG. 4) to the second position 512. Additionally, the spring 151 is disengaged with the tactile switch 155. Specifically, the tactile arm 251 of the tactile switch 155 is out of direct contact with the spring arm 353. The actuator 253 of the tactile switch 155 is also out of direct contact with the tactile arm 251, thus causing the tactile switch 155 to be at an OFF state 552. For example, the OFF state 552 of the tactile switch 155 corresponds to a condition that the movable component 110 is in the second position 512 and disengaged with the non-movable component 120 (shown in FIG. 1 and FIG. 2).

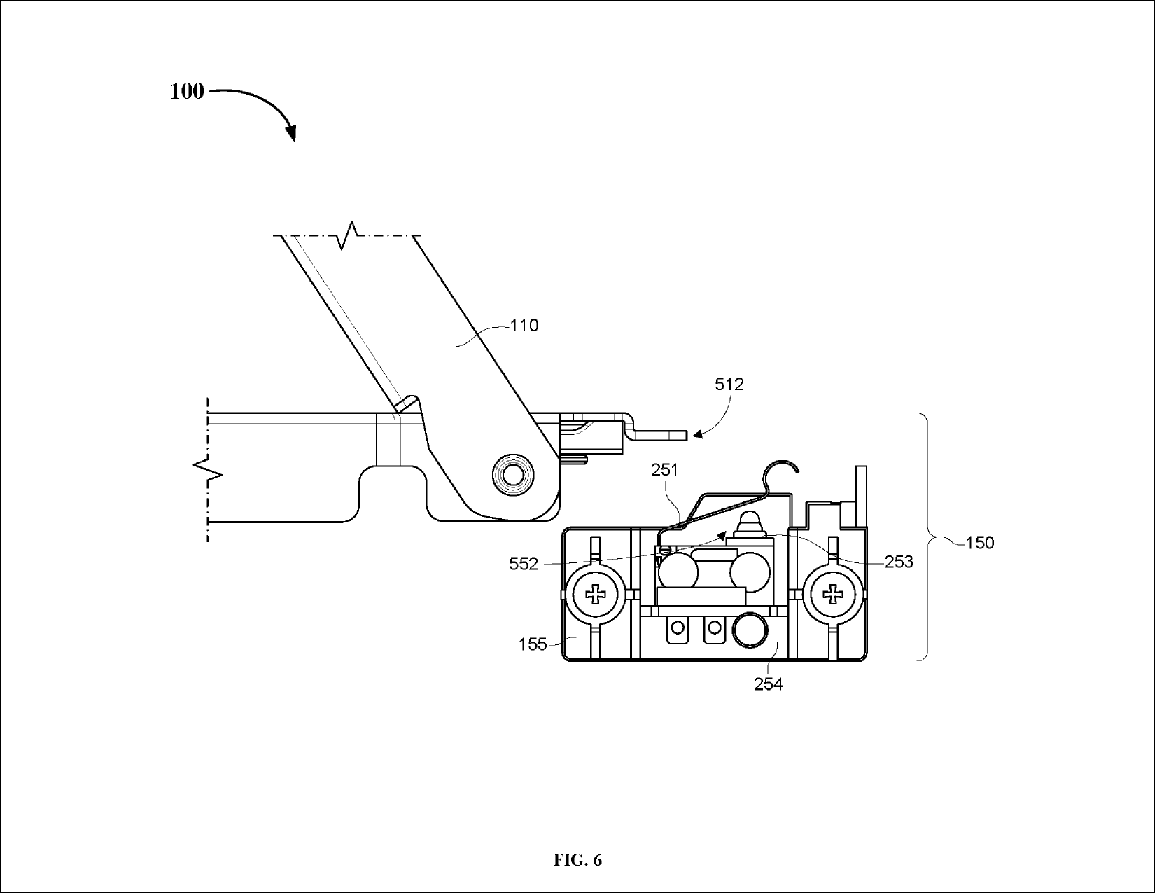

FIG. 6 illustrates the movable component 110 being at the second position 512 where the movable component 110 is pivoted away from the tactile switch 155 of the tactile sensing device 150. Specifically, the movable component 110 moves out of engagement with the non-movable component 120, as shown in FIG. 1. In some implementations, the movable component 110 pivots normally to the longitudinal body 254 of the tactile switch 155 and out of engagement with the non-movable component 120. This vertical movement causes the movable component 110 to move from the first position 411 to the second position 512. Additionally, the spring 151 is disengaged with the tactile switch 155. The actuator 253 of the tactile switch 155 is also out of direct contact with the tactile arm 251, thus causing the tactile switch 155 to be at the OFF state 552.

As shown in FIG. 4 to FIG. 6, the tactile sensing device 150 is designed to monitor the first position 411 and the second position 512 of the movable component 110 with respect to the non-movable component 120. For example, the movable component 110 can move from the first position 411 to the second position 512 by sliding or pivoting or both. In response to this movement, the spring arm 353 moves to the second position 512 in which the spring arm is out of contact with the tactile arm 251. Additionally, the actuator 253 is out of direct contact with the tactile arm 251. Thus, the tactile switch 155 changes from the ON state 451 to the OFF state 552 and outputs an alert that the movable component 110 is in the second position 512. For example, in a server, a top cover moves slightly to cause disengagement with a chassis. The cover changes from the first position to the second position. Consequently, the tactile switch changes from the ON (engaged) state to the OFF (disengaged) state, thus outputting an alert that the server chassis is open.

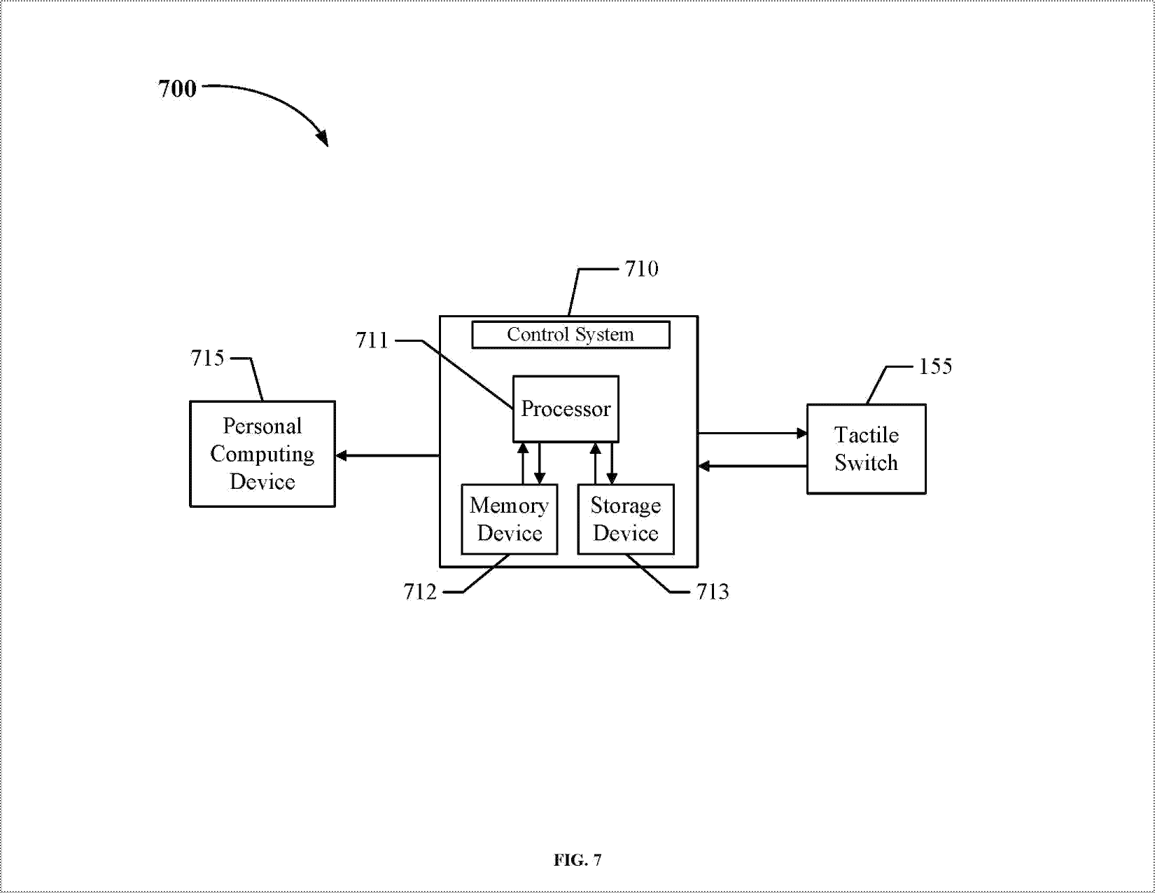

FIG. 7 illustrates electrical connections and data/signal flows among various components of a computing system 700. Specifically, the computing system 700 includes a control system 710. The control system 710 is electrically connected and communicates with the tactile switch 155, and a personal computing device 715. The control system 710 includes one or more processors 711, a memory device 712, and a storage device 713. The memory device 712 has stored machine-readable instructions. The one or more processors 711 is electrically connected and digitally communicates with the memory device 712 and the storage device 713. Moreover, the machine-readable instructions may be saved in the storage device 713. Further, the personal computing device 715 includes a personal computer, a smartphone, a smartwatch, and any other suitable device.

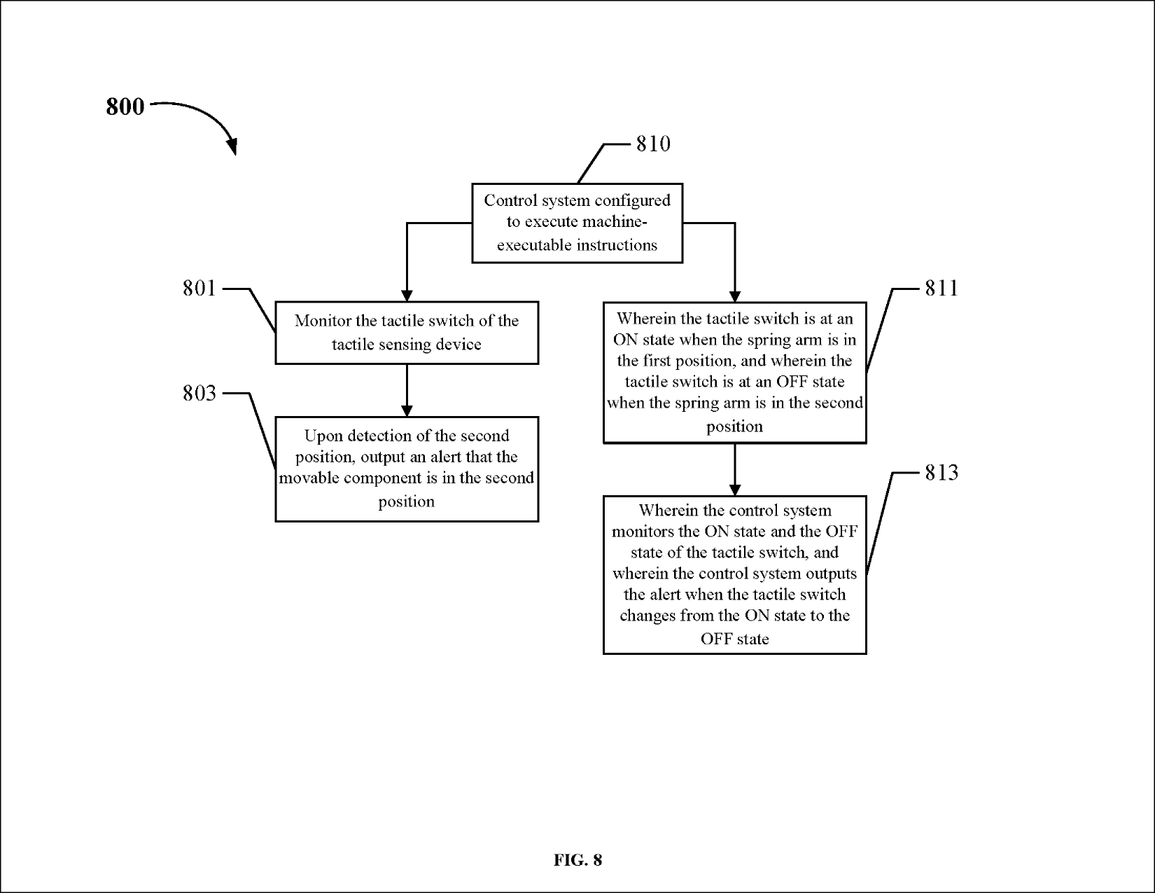

FIG. 8 illustrates a computing system 800 that has a control system 810 configured to monitor movements of a movable component by a tactile sensing device. Specifically, the control system is configured to execute machine-executable instructions to cause the computing system 800 to monitor a tactile switch of the tactile sensing device (Step 801). The tactile switch has a tactile arm and an actuator. Moreover, upon detection of the second position, the method outputs an alert that the movable component is in the second position (Step 803). The second position is where the movable component is disengaged with the non-movable component. At the second position, a spring arm of the spring is out of contact with the tactile arm of the tactile switch, and the tactile arm is out of contact with the actuator.

As shown in FIG. 8, in an alternative implementation, the tactile switch is at an ON state when the spring arm is in the first position, and the tactile switch is at an OFF state when the spring arm is in the second position (Step 811). In a further alternative implementation, the control system monitors the ON state and the OFF state of the tactile switch, and outputs the alert when the tactile switch changes from the ON state to the OFF state (Step 813). When the movable component of the computing system 800 moves out of engagement with the non-movable component, e.g., to the second position, the tactile switch changes from the ON state to the OFF state. Moreover, the control system outputs an alert to the personal computing device of the user.

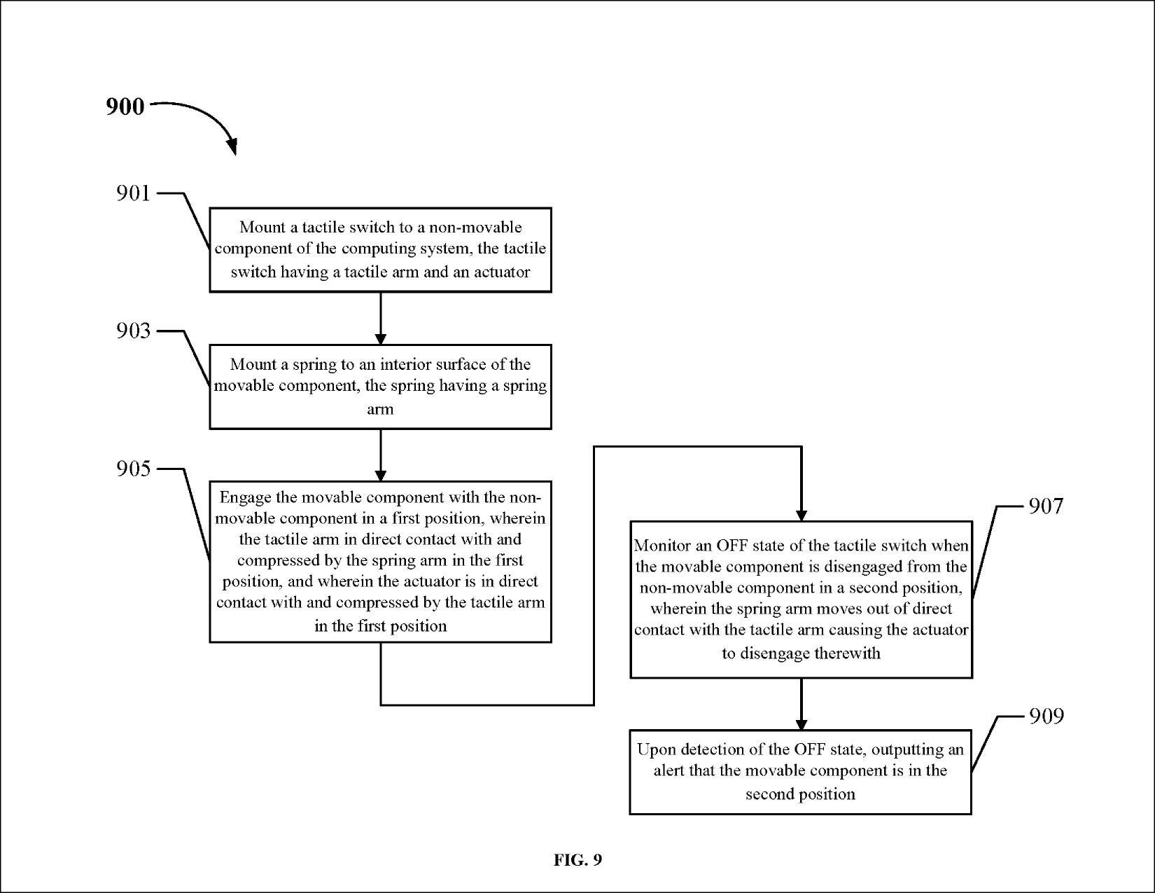

FIG. 9 illustrates a method 900 for monitoring movements of a movable component with respect with a non-movable component of a computing system using a tactile sensing device. The tactile sensing device has a tactile switch. The tactile switch has a tactile arm and an actuator. The method 900 includes mounting the tactile switch to a non-movable component of the computing system (Step 901). The method 900 also includes mounting a spring to an interior surface of the movable component (Step 903). The spring has a spring arm. Moreover, the method 900 includes engaging the movable component with the non-movable component in a first position (Step 905). In the first position, the tactile arm is in direct contact with and compressed by the spring arm, and the actuator is in direct contact with and compressed by the tactile arm. Further, the method 900 includes monitoring an OFF state of the tactile switch when the movable component is disengaged from the non-movable component in a second position (Step 907). In the second position, the spring arm moves out of direct contact with the tactile arm causing the actuator to disengage with the tactile arm. Upon detection of the OFF state, the method 900 includes outputting an alert that the movable component is in the second position (Step 909). Therefore, the method 900 efficiently and precisely monitors the movements of the movable component when the movable component moves out of the first position, by sliding, pivoting, or flipping. Accordingly, the method 900 eliminates or minimizes false alerts that the movable component moves to the second position while still staying in the first position.

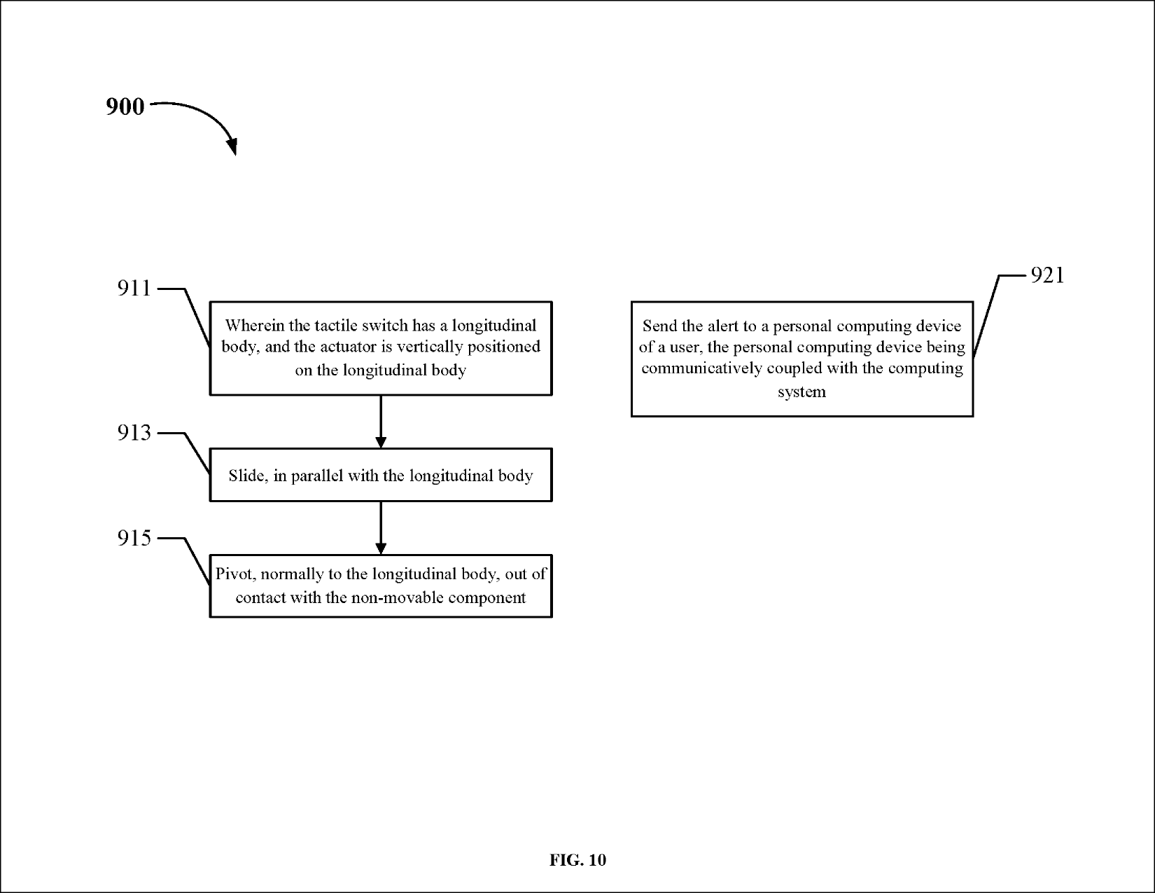

FIG. 10 illustrates alternative methods of the method 900 for monitoring movements of the movable component with respect with the non-movable component of the computing system using the tactile sensing device. In some implementations, the method 900 includes the tactile switch that has a longitudinal body (Step 911). Additionally, in Step 911, the actuator is vertically positioned on the longitudinal body. Moreover, the method 900 includes sliding, in parallel with the longitudinal body of the tactile switch (Step 913). Alternatively, the movable component pivots, normally to the longitudinal body, out of contact with the non-movable component (Step 915). In either case, the method 900 outputs the alert once the movable component moves out of contact with the non-movable component and changes to the second position. This movement results in the tactile switch changing from the ON state to the OFF state. Furthermore, the method 900 includes coupling the tactile switch to a switch holder and mounting the switch holder to the non-movable component.

As shown in FIG. 10, the method 900 further includes sending the alert to a personal computing device of a user, the personal computing device being communicatively coupled with the computing system (Step 921).

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above-described embodiments. Rather, the scope of the disclosure should be defined in accordance with the following claims and their equivalents.

What is claimed is:

1. A tactile sensing device for a computing system, the tactile sensing device comprising:
a movable component that is engaged with a non-movable component in a first position, the movable component being disengaged from the non-movable component in a second position;
a spring in contact with the movable component and having a spring arm; and
a tactile switch in contact with the non-movable component, the tactile switch having:
a tactile arm that is in direct contact with and compressed by the spring arm in the first position, in response to movement of the movable component from the first position to the second position, the spring arm being movable to the second position in which the spring arm is out of contact with the tactile arm, and
an actuator that is in direct contact with and compressed by the tactile arm in the first position, the actuator being uncompressed in the second position,
wherein, in response to the spring arm being in the second position, the tactile switch outputs an alert that the movable component is in the second position.

2. The tactile sensing device of claim 1, further comprising a switch holder, the tactile switch being mounted thereon.

3. The tactile sensing device of claim 2, wherein the switch holder is mounted on an interior surface of the non-movable component.

4. The tactile sensing device of claim 1, wherein the spring further includes a base and a support, the support coupling the base and the spring arm on opposite ends thereof, the base being mounted on an interior surface of the movable component.

5. The tactile sensing device of claim 4, wherein the spring arm is oriented at an angle between about 0 degrees to about 90 degrees relative to the base.

6. The tactile sensing device of claim 1, wherein the tactile arm has a curved end that is configured to engage with the spring arm.

7. The tactile sensing device of claim 6, wherein the curved end of the tactile arm has an arc shape.

8. The tactile sensing device of claim 1, wherein the non-movable component is a sidewall of a chassis of the computing system.

9. The tactile sensing device of claim 1, wherein the movable component is a cover.

10. The tactile sensing device of claim 1, wherein the computing system is a server.

11. The tactile sensing device of claim 1, wherein the tactile switch has a longitudinal body, and the actuator is vertically positioned on the longitudinal body.

12. The tactile sensing device of claim 11, wherein the movable component is configured to:
slide, in parallel with the longitudinal body, or
pivot, normally to the longitudinal body, out of engagement with the non-movable component.

13. A computing system comprising:
a movable component that is engaged with a non-movable component in a first position, the movable component being disengaged from the non-movable component in a second position;
a tactile sensing device configured to detect movements of the movable component from the first position to the second position, the tactile sensing device including:
a spring in contact with the movable component and having a spring arm;
a tactile switch in contact with the non-movable component, the tactile switch having:
a tactile arm that is in direct contact with and compressed by the spring arm in the first position, in response to movement of the movable component from the first position to the second position, the spring arm being movable to the second position in which the spring arm is out of contact with the tactile arm,
an actuator that is in direct contact with and compressed by the tactile arm in the first position, the actuator being uncompressed in the second position; and
a control system having one or more processors configured to execute machine-executable instructions to cause the computing system to:
monitor the tactile switch of the tactile sensing device; and
upon detection of the second position, output an alert that the movable component is in the second position.

14. The tactile sensing device of claim 13, wherein the tactile switch is at an ON state when the spring arm is in the first position, and wherein the tactile switch is at an OFF state when the spring arm is in the second position.

15. The tactile sensing device of claim 14, wherein the control system monitors the ON state and the OFF state of the tactile switch, and wherein the control system outputs the alert when the tactile switch changes from the ON state to the OFF state.

16. A method of detecting movements for a movable component of a computing system, the method comprising:
mounting a tactile switch to a non-movable component of the computing system, the tactile switch having a tactile arm and an actuator;
mounting a spring to an interior surface of the movable component, the spring having a spring arm;
engaging the movable component with the non-movable component in a first position, wherein the tactile arm in direct contact with and compressed by the spring arm in the first position, and wherein the actuator is in direct contact with and compressed by the tactile arm in the first position;
monitoring an OFF state of the tactile switch when the movable component is disengaged from the non-movable component in a second position, wherein the spring arm moves out of direct contact with the tactile arm causing the actuator to disengage therewith; and
upon detection of the OFF state, outputting an alert that the movable component is in the second position.

17. The method of claim 16, further comprising:
sending the alert to a personal computing device of a user, the personal computing device being communicatively coupled with the computing system.

18. The method of claim 16, wherein the tactile switch has a longitudinal body, and the actuator is vertically positioned on the longitudinal body.

19. The method of claim 18, wherein the movable component is configured to:
slide, in parallel with the longitudinal body, or
pivot, normally to the longitudinal body, out of contact with the non-movable component.

20. The method of claim 16, further comprising:
coupling the tactile switch to a switch holder; and
mounting the switch holder to the non-movable component.
